(19) United States
(12) Patent Application Publication
(10) Pub. No.: US 2025/0079239 A1
(43) Pub. Date: Mar. 6, 2025

(54) SELECTIVE CAPPING FOR GATE-ALL-AROUND FIELD EFFECT TRANSISTORS

(71) Applicant: Applied Materials, Inc., Santa Clara, CA (US)

(72) Inventors: Jiang LU, Milpitas, CA (US); Shumao ZHANG, San Jose, CA (US); Liqi WU, San Jose, CA (US); Yiyang WAN, Sunnyvale, CA (US); Weifeng YE, San Jose, CA (US); Jianqiu GUO, San Jose, CA (US); Dong WANG, Santa Clara, CA (US); Qihao ZHU, Sunnyvale, CA (US)

(21) Appl. No.: 18/459,524

(22) Filed: Sep. 1, 2023

(51) Int. Cl. H01L 21/768; H01L 21/3205

(52) U.S. Cl. CPC H01L 21/76879; H01L 21/32053; H01L 21/7685; H01L 21/76876

(57) ABSTRACT

Embodiments of the disclosure include a method of forming a gate-all-around (GAA) contact structure on a semiconductor substrate. The method will include removing material from surfaces of a feature formed in a surface of a substrate that includes a plurality of features that each include a plurality of source/drain contact surfaces, selectively forming a reaction product material over a surface of each of the plurality of source/drain contact surfaces, heating the substrate to a first temperature to remove the reaction product material from the surface of each of the plurality of contacts, selectively forming a first metal layer on the surface of each of the plurality of contacts, selectively forming a second metal layer on the first metal layer, and filling the feature with a conductor material, wherein the conductor material comprises tungsten (W) or molybdenum (Mo).

### BACKGROUND

### Field

Embodiments described herein generally relate to semiconductor device fabrication, and more particularly, to systems and methods of forming gate contact structures in gate-all-around field-effect transistors.

### Description of the Related Art

Integrated circuits have evolved into complex devices that can include billions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. An example of such devices may include high-performance computing, mobile devices, internet of things (IoT) devices, memory (for example, DRAM (dynamic random access memory)) and logic devices, including both planar and three-dimensional structures. Three-dimensional structures include finFET (fin field-effect transistor, MOSFET (metal-oxide-semiconductor field-effect transistor) devices, or GAA FET (gate-all-around field-effect transistor) devices.

A GAA FET is an advanced transistor design that offers improved performance and power efficiency compared to traditional FETs such as the finFET (fin field-effect transistor, MOSFET (metal-oxide-semiconductor field-effect transistor). It consists of a channel region surrounded by a gate structure on all sides, providing superior control over the flow of electrons. The GAA architecture allows for enhanced electrostatic control and reduced leakage current, enabling higher switching speeds, lower power consumption, and improved scalability. With its three-dimensional gate configuration, GAA FETs exhibit excellent control over short-channel effects, enabling the design of highly compact and efficient electronic devices for a wide range of applications, including high-performance computing, mobile devices, and internet of things (IoT) devices.

An example a GAA FET device includes of a channel region surrounded by a gate structure on all sides providing superior control over the flow of electrons. Source/drain regions are provided opposing ends of the gate structure. The source and drain regions are generally heavily doped regions of the semiconductor substrate. Usually a silicide layer, for example a titanium silicide layer, is required to form a reliable contact structures at the formed source and drain regions.

In a traditional middle-end-of-the-line (MEOL) contact junction formation process, a feature, such as a via or trench, is fabricated in the semiconductor substrate. A silicon (Si) or silicon/germanium (SiGe)-comprising contact region is formed in the trench or via bottom. MEOL contact junctions allow connections between front-end-of-the-line (FEOL) semiconductor structures and back-end-of-the-line (BEOL) interconnects. Contacts with a low resistivity are desirable in semiconductor devices. However, when a MEOL contact junction has a relatively high resistance, a poor connection is created at the MEOL contact junction, which reduces the overall performance of the packaged semiconductor structures.

In 3D device structures, such as FinFETs, silicide contacts are needed to be formed on the exposed portions of the silicon-based source/drain layers formed on the sidewalls of the deep high-aspect-ratio (HAR) holes or deep HAR trenches leaving little to no space to reliably form the GAA gate contact structures. Conventional deposition techniques typically form the silicide layers at one specific and optimized depth, but the species concentration gradient developed during transport in the deep holes/trenches will inherently cause non-uniformity of deposition. HAR holes or deep HAR trenches further magnify the non-uniformity of deposition. This conventional approach for forming the silicide layers in the features results in variations in the silicide layer properties which, among other things, leads to variations in the electrical characteristics of the 3D device.

Therefore, there is a need in the art for a selective process that is used to efficiently and quickly form reliable low resistance contact structures for GAA FET devices.

### SUMMARY

Embodiments described herein generally relate to semiconductor device fabrication, and more particularly, to systems and methods of forming gate contact structures in gate-all-around field-effect transistors. The method includes the following.

Removing material from surfaces of a feature formed in a surface of a substrate, wherein the feature includes a plurality of contact structures disposed within the feature formed in the substrate, the contact structures include a plurality of contacts that each include silicon (Si) or silicon germanium (SiGe), and each of the plurality of contacts are spaced apart in a first direction by a dielectric layer. The method of removing material includes selectively forming a reaction product material over a surface of each of the plurality of contacts, then heating the substrate to a first temperature to remove the reaction product material from the surface of each of the plurality of contacts.

Selectively forming a first metal layer on the surface of each of the plurality of contacts. Forming a second metal layer on the first metal layer, wherein forming the second metal layer on the first metal layer includes selectively depositing the second metal layer on the first metal layer, and selectively forming the second metal layer includes exposing the surface of the selectively formed first metal layer to a fluorine-free metal containing precursor to form the second metal layer.

Filling the feature with a conductor material, wherein the conductor material includes tungsten (W) or molybdenum (Mo), and depositing a capping layer on the conductor material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic top view of a multi-chamber processing system, according to embodiments described herein.

FIG. 2 depict a process flow diagram of a method of forming a semiconductor structure according to embodiments described herein.

FIG. 3 is a schematic isometric view of an example GAA FET semiconductor structure according to embodiments described herein.

FIGS. 4A-J are schematic cross-sectional views of a portion of a semiconductor structure according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following disclosure, reference may be made to one or more embodiments. However, one of skill in the art does appreciate that the disclosure is not limited to specifically to the described embodiments. Rather, any combination of features and elements, whether related to different embodiments or not, is envisioned to implement and practice one or more embodiments provided by the disclosure. Furthermore, although the one or more embodiments presented in the disclosure may achieve advantages over other possible solutions, the prior art (if existing), and combinations thereof, whether or not a particular advantage is achieved by a given embodiment is not limited by this disclosure. The aspects, features, embodiments, and advantages provided are merely illustrative. These are not considered elements or limitations of the appended claims except where explicitly recited in one or more of the Claims. Likewise, one of skill in the art should not construe a reference to “the disclosure” as a generalization of any disclosed subject matter.

A “substrate” as used in this application may refer to a substrate or material surface formed on a substrate upon which film processing is performed during a fabrication process. For example, a substrate surface which may be processed may be comprised of a material such as, but not limited to, Silicon (Si), Silicon Oxide (SiO₂), strained Si, Si on insulator (SOI), carbon doped Silicon Oxides (SiOₓ), amorphous Si, doped Si, pre-amorphization implantation (PAI) Si, Germanium (Ge), PAI-SiGe, Gallium Arsenide (GaAs), glass, sapphire, and any other conductive materials depending on the application, such as metals, metal nitrides, and metal alloys. Substrates include by way of example and without limitation semiconductor wafers. Substrates may be exposed to a treatment process(es) to polish, etch, reduce, oxidize, or anneal substrate surface.

The terms “precursor”, “reactant”, “reactive gas”, and similar such terms referring to chemical species, as used in this application may refer to refer to one or more chemical species that may react with one or more exposed surfaces of a substrate or with one another and the resultant thereof then react with the exposed surfaces of a substrate.

The terms “CPU,” “processor,” “at least one processor” or “one or more processors” generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions. Similarly, “a memory,” “at least one memory” or “one or more memories” generally refers to a single memory configured to store data and/or instructions, multiple memories configured to collectively store data and/or instructions.

### Processing System Example

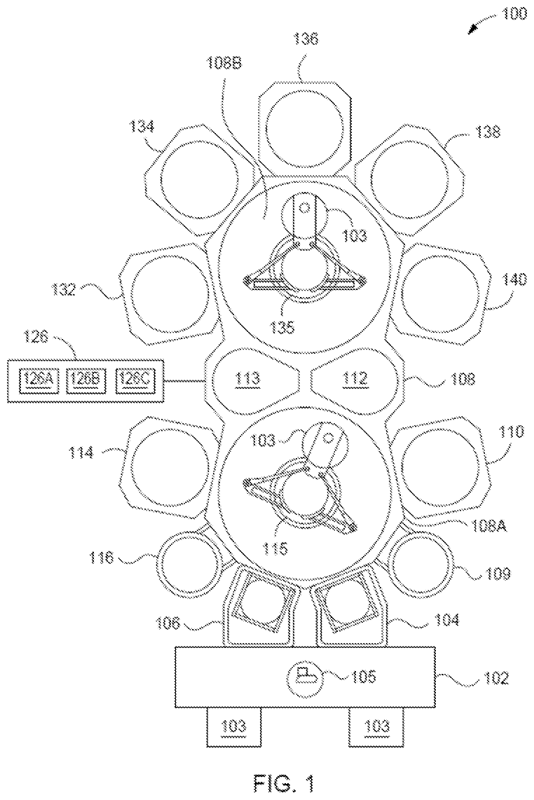

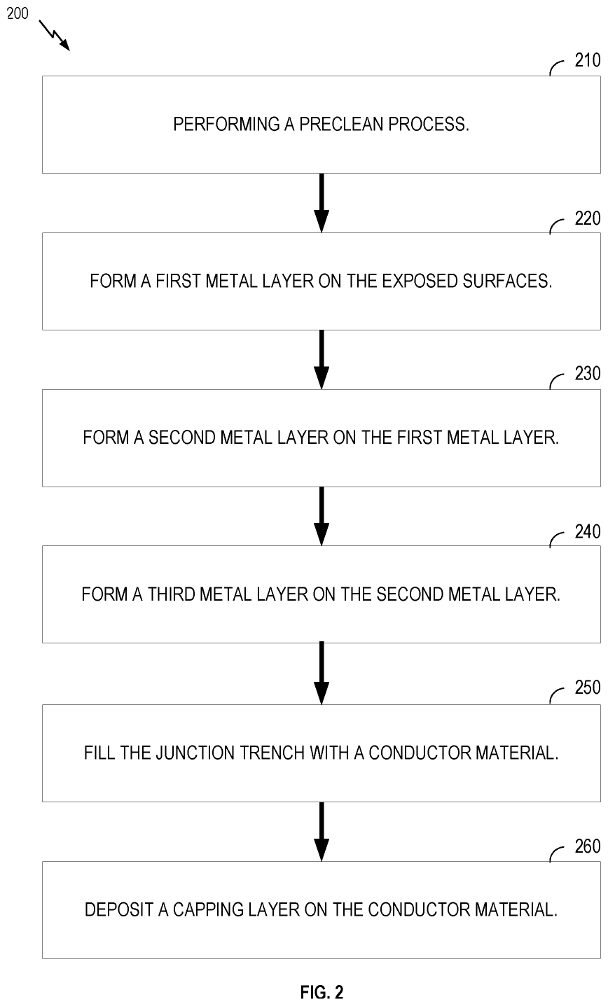

FIG. 1 illustrates a schematic representation of a processing system 100 for use with one or more embodiments of the disclosure. In one or more embodiments, the processing system 100 may be utilized to perform all or a portion of the method 200 of FIG. 2.

As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 Torr), or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

Examples of a processing system that may be suitably modified in accordance with the teachings provided include the Endura® integrated processing systems or other suitable processing systems commercially available from Applied Materials, Inc., located in Santa Clara, California (CA), United States of America. One may envision that other processing systems, including those from other manufacturers, may be adapted to benefit from aspects described.

FIG. 1 is a schematic top view of the processing system 100 (also referred to as a “processing platform”), according to embodiments described herein. The processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, and 106, the degas chambers 109, and 116, the pre-clean chambers 110, and 114 and the pass-through chambers 112, and 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective CVD or ALD deposition processes. In one example, the processing chamber 110 or 114 may be a Selectra™ Etch chamber available from Applied Materials of Santa Clara, Calif. In one example, the processing chamber 110 or 114 may be a SiCoNi™ Pre-clean chamber available from Applied Materials of Santa Clara, Calif. In one example, the processing chambers 132, 134, 136, 138, or 140 may be a Volta™ CVD/ALD chamber, or Encore™ PVD chambers available from Applied Materials of Santa Clara, Calif.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

### Gate-All-Around Field Effect Transistor Structure

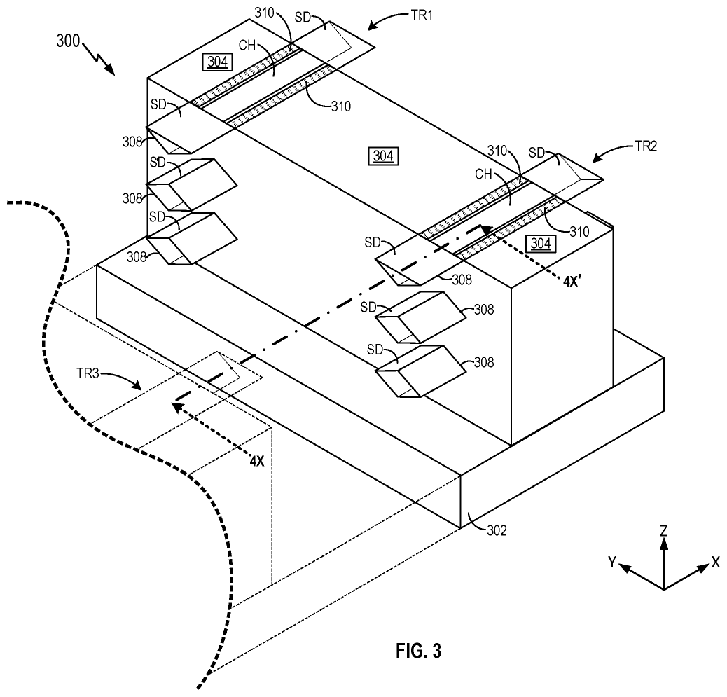

The example Gate-All-Around Field Effect Transistor (GAA FET) semiconductor structure 300 of FIG. 3 includes a substrate 302 having a first GAA FET module TR1 formed and a second GAA FET module TR2 formed. The GAA FET module TR1 and the GAA FET module TR2 are electrically isolated, by an inter-module insulating layer 304, from each other and from other GAA FET modules in the semiconductor structure 300 that are not shown in FIG. 3. Shown in section is a partial depiction of a GAA FET module TR3 which would share a portion of the substrate 302 with TR1 and TR2 and forming an opening between TR2 and TR3 described later.

The term “substrate” as used herein refers to a layer of material that serves as a basis for subsequent processing operations and includes a surface to be cleaned. The substrate 302 may be a silicon based material or any suitable insulating materials or conductive materials as needed. The substrate 302 may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire. The inter-module insulating layer 304 may be formed of silicon-containing dielectric material such as silicon oxide, or silicon nitride.

Each of the GAA FET modules, TR1 and TR2 illustrated in FIG. 3, include a channel region CH and source/drain regions SD that are separated by the channel region CH in the X-direction. The source/drain regions SD may be wider in the Y-direction than the channel region CH. The source/drain regions SD may be separated from other source/drain regions SD by the inter-module insulating layer 304 in the X-direction, the Y-direction, and/or Z-direction.

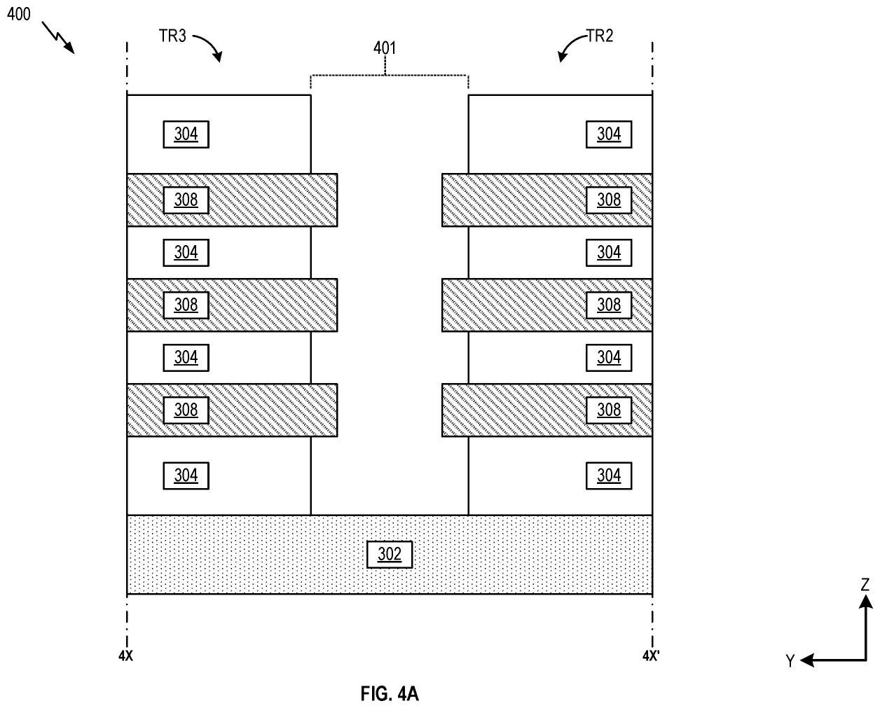

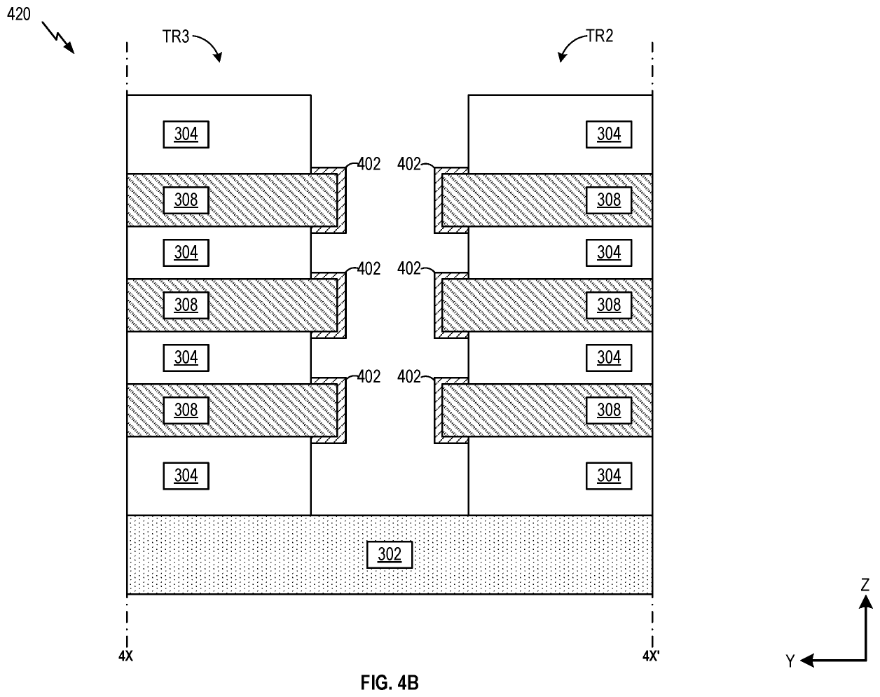

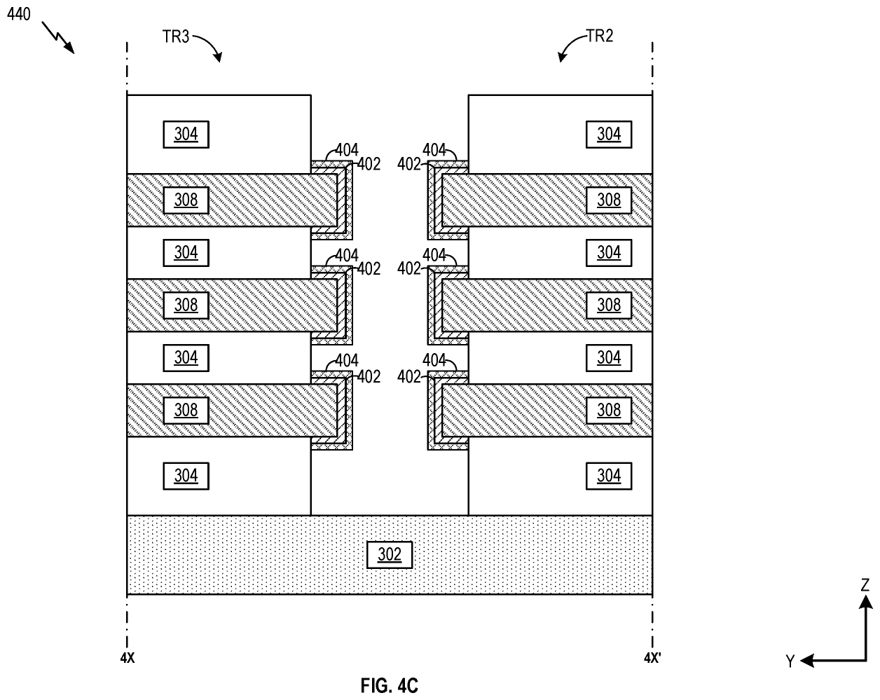

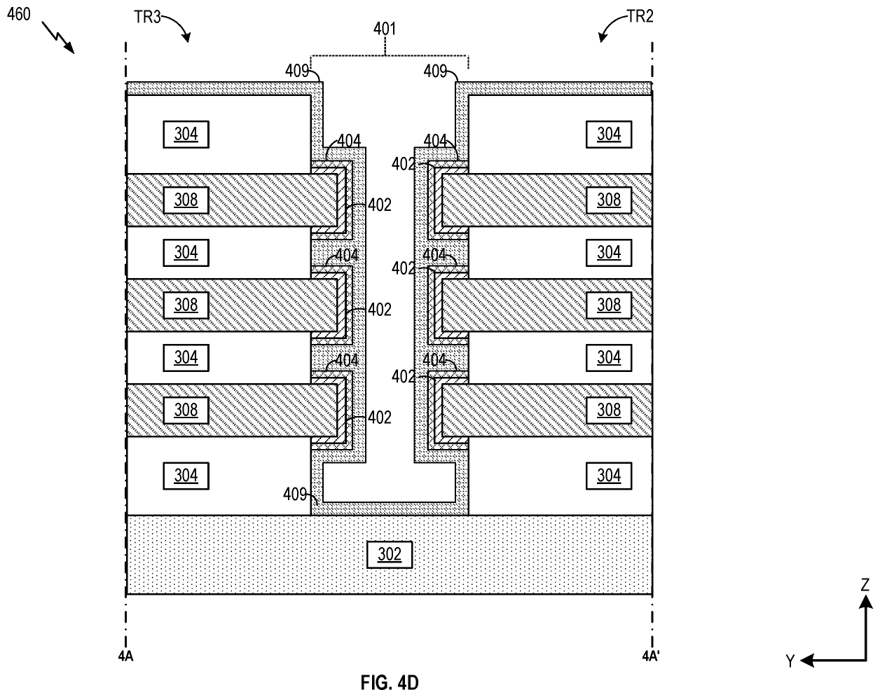

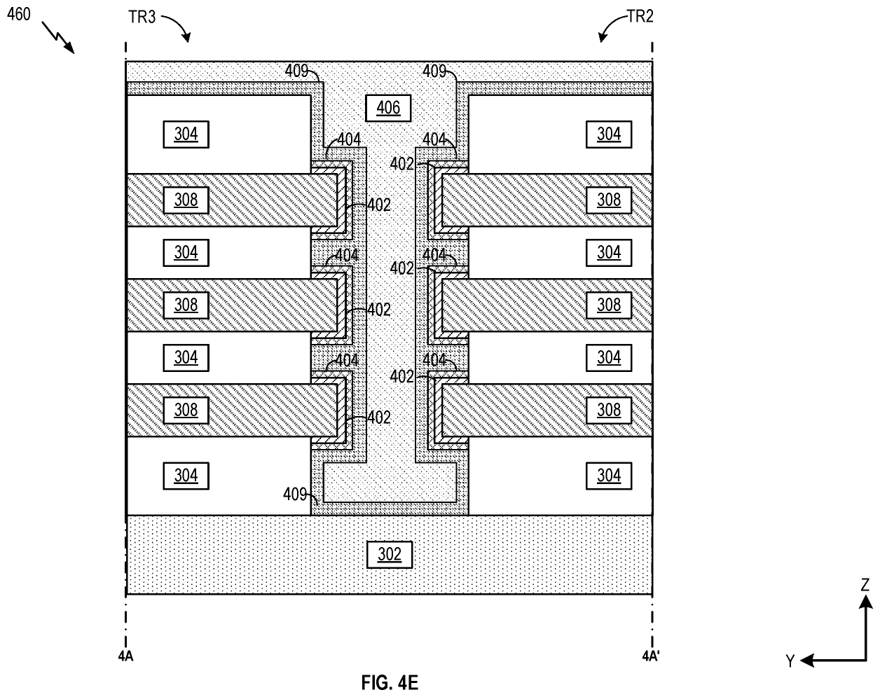

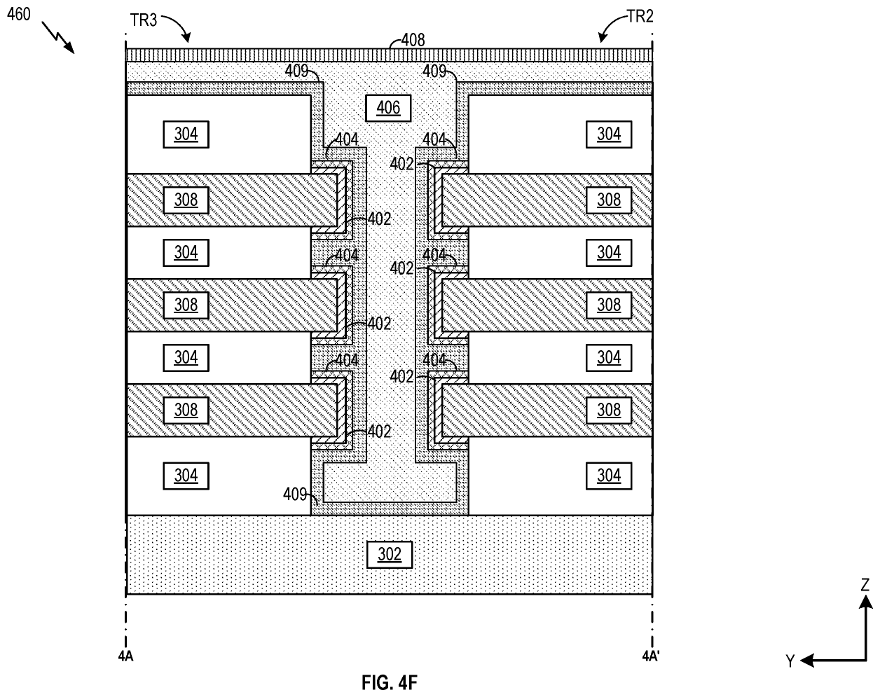

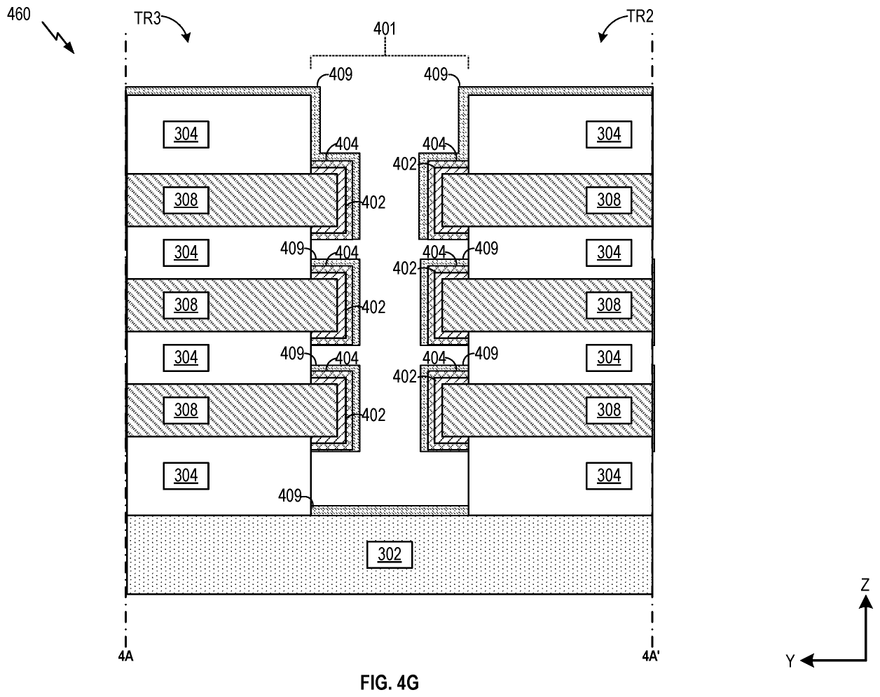

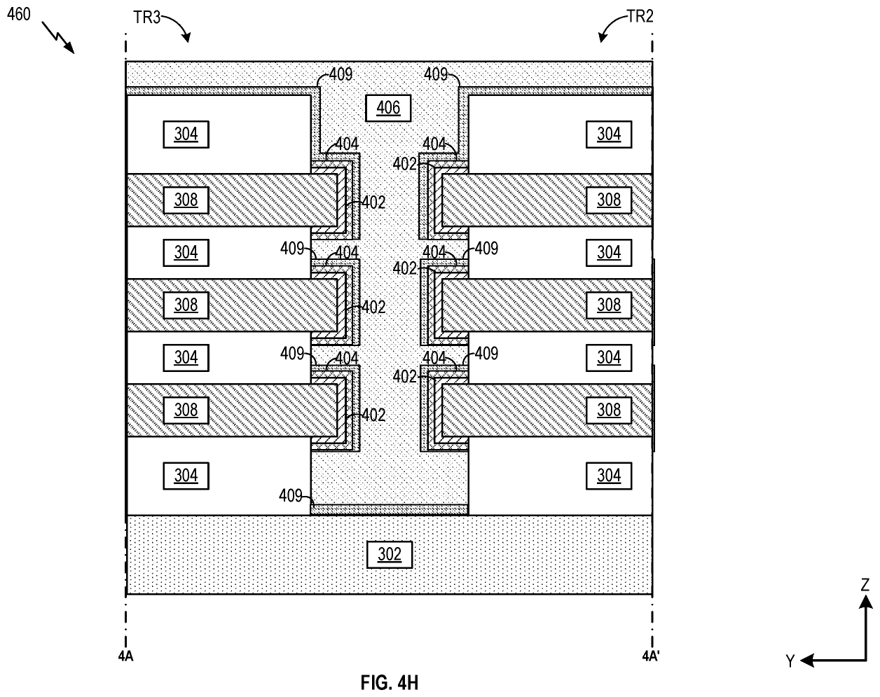

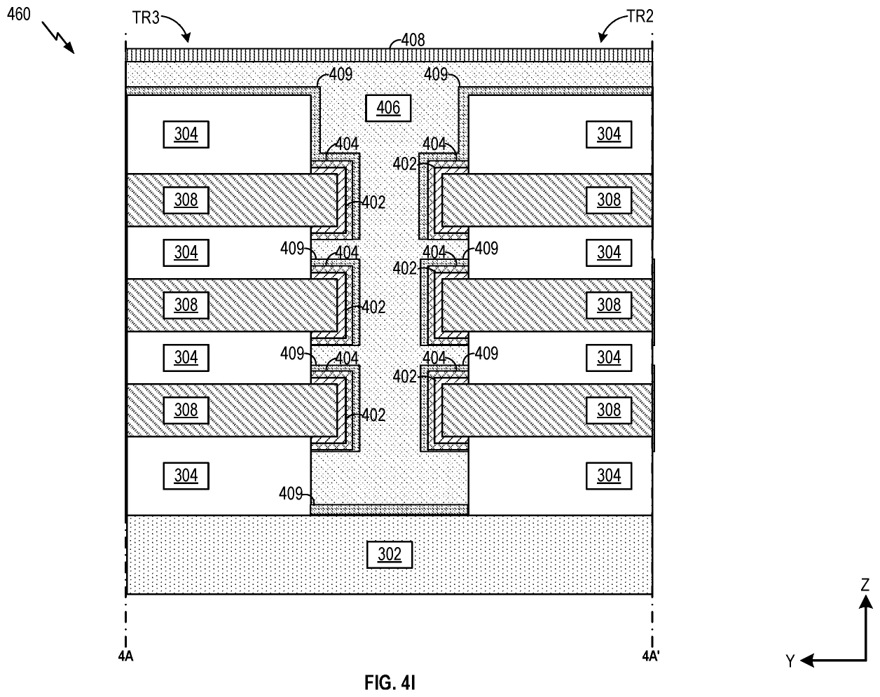

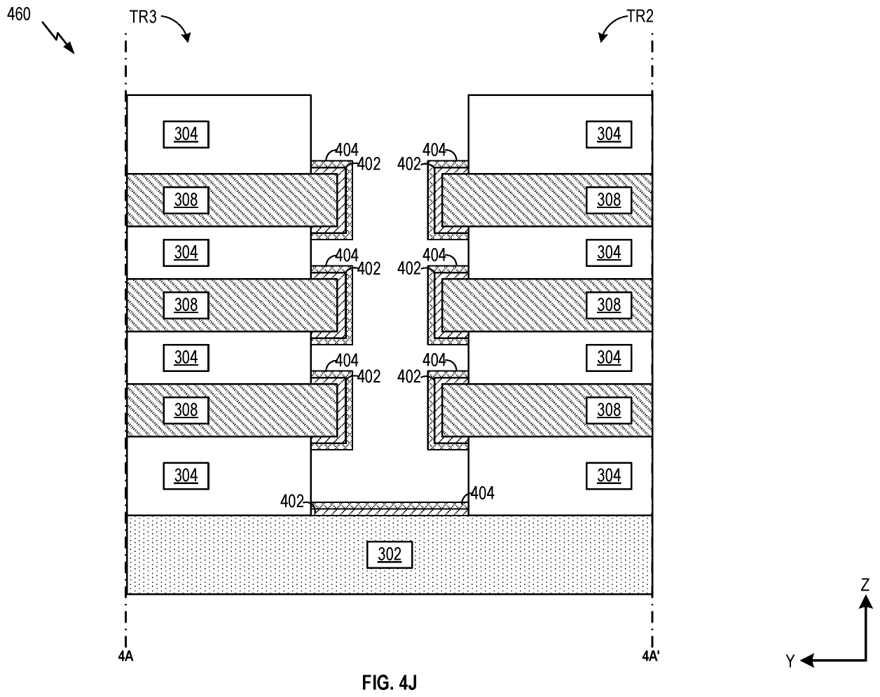

For purposes of discussion, the source/drain (SD) regions illustrated in FIG. 3 include an exposed portion of a silicon-containing contact structure 308, which has been exposed in a HAR opening (e.g., opening 401 in FIG. 4A and FIG. 4G) within the semiconductor structure 300 that is formed over a region of the substrate 302. In this example, the GAA FET modules, TR1 and TR2, are each comprised of three SD regions, however, more or less SD regions may be formed in various types of FET devices. In some embodiments, there may be as few as one SD region, or hundreds of SD regions, oriented in the X-direction, the Y-direction, and/or Z-direction. The silicon-containing contact, such as silicon-containing contact 308, may include a material useful for forming a contact, such as a silicon-based material or a material contain silicon, such as a silicon/germanium (SiGe)-based material. One or more of the silicon-containing contacts 308 may additionally or alternately include a material that includes a dopant atom, such as an n-type or p-type dopant.

The channel regions CHs of each of the GAA FET modules, TR1 and TR2, may include adjacent parallel gate structures 310 extending along the X-direction within the inter-module insulating layer 304. Each gate structure 310 may include a gate metal layer and a gate dielectric layer that is disposed between the channel region CH and the gate metal layer. In some embodiments, the gate dielectric may include a dielectric material (e.g., hafnium dioxide (HfO₂), zirconium dioxide (ZrO₂), and/or titanium dioxide (TiO₂)) with a dielectric constant (κ) higher than silicon dioxide (SiO₂) (e.g., κ=3.9). In some embodiments, the dielectric material may be referred to as a high-κ dielectric. In some embodiments, the gate metal layer may itself be formed of multiple metal layers each comprised of an electrically conductive material. The electrically conductive material may include various metal alloys, metals, or conductive ceramics including but is not limited to, one or more of Aluminum (Al), chromium (Cr), cobalt (Co), copper (Cu), gold (Au), hafnium (Hf), iridium (Ir), iron (Fe), lanthanum (La), manganese (Mn), molybdenum (Mo), niobium (Nb), platinum (Pt), rhodium (Rh), ruthenium (Ru), silver (Si), tantalum (Ta), tin (Sn), titanium (Ti), tungsten (W), vanadium (V), yttrium (Y), zirconium (Zr), and combinations thereof.

### Processing Sequence Example

Building from the processing system 100 and information provided in FIGS. 1, 2 and 3, embodiments of the disclosure include a method 200 of forming a semiconductor device. FIGS. 4A-4F are schematic drawings of side cross-sectional views of portions of a semiconductor substrate illustrated in FIG. 3 undergoing a process disclosed in method 200. The cross-sectional views, FIGS. 4A-F, view of a portion of a semiconductor structure 300 from 4X to 4X′ in FIG. 3, viewed along the Y-direction. The process flow diagram of a method 200 depicted in FIG. 2 may be best understood with reference to FIGS. 4A-F. Alternative embodiments utilizing method 200 of FIG. 2 understood with reference to FIGS. 4G-I, and FIG. 4J.

Prior to the first operation 210 of method 200, surface contamination may be present on the boundary surfaces of the device features. These surface contaminates, such as native oxides, may be formed on one or more of the surfaces of the device features, such as a silicon dioxide formed on exposed surfaces. The surface contaminants may also be of varying thickness depending on the circumstances of formation, such as exposure to the atmosphere or oxygen while the substrate was at an elevated temperature.

The first operation 210 of method 200 includes exposing of each contact structure 308 within a plurality of stacked contact structures 308 disposed within a opening 401 (FIG. 4A) formed in a semiconductor substrate to a precleaning process, wherein the exposed surfaces comprise silicon, and each of the plurality of stacked contact structures 308 are spaced apart in a first direction within the opening 401.

The exposure of each contact structure 308 within a plurality of stacked contact structures begins with a cleaning process performed during the first operation 210 of method 200 which may be performed in a process chamber, such as processing chamber 110 or 114 within the processing system 100. In one example, the cleaning process converts all of the exposed silicon oxide containing material, including any semiconductor substrate silicon dioxide exposed within the device feature, into a cleaning process reaction product material that will include a silica salt hydrate containing material, which for the purposes of simplicity is referred to in the remainder of this application as simply “silica salt”. In another example, the cleaning process performed in first operation 210 of method 200 includes utilizing an etching process, such as an ammonium fluoride dry etching process. Both ammonium fluoride and ammonium hydrogen fluoride are reactive with silicon oxides at in range of from about −30° C. to about 100° C. using a dry etching process versus other silicon-containing materials. For the purposes of this disclosure, utilizing either or both ammonium fluoride (NH₄F) or ammonium hydrogen fluoride (NH₄F.HF) are collectively referred to as “ammonium fluoride”. As well, the use of either or both ammonium fluoride or ammonium hydrogen fluoride in an etching process is referred to as the “ammonium fluoride etching process”.

In one example, the cleaning process preformed in first operation 210 of method 200 includes introducing both a hydrogen-containing precursor and a fluorine-containing precursor into the plasma/carrier gas. For example, ammonia (NH₃) may be the hydrogen-containing precursor and nitrogen trifluoride (NF₃) may be the fluorine-containing precursor introduced into the plasma/carrier gas mixture. The introduction of both the hydrogen-containing precursor and the fluorine-containing precursor into the plasma/carrier gas causes both precursors to become energized on a molecular level. In such an energized states, disassociation of the precursors occurs in the carrier gas, forming a first plasma-disassociated hydrogen-containing precursor and a first plasma-disassociated fluorine-containing precursor. The dissociated atomic species then recombine in the carrier gas (gas phase) to form one or both ammonium fluoride (NH₄F) or ammonium hydrogen fluoride (NH₄F.HF) species. In one or more embodiments, the combined flow rates of hydrogen-containing and fluorine-containing precursors are in a range of from about 1 volume percent (vol. %) to 70 vol. % of the overall gas mixture, including the endpoint values and all values in between, whereas the remainder of the gas mixture comprises, consists, or consists essentially of the carrier gas. In one or more embodiment, a purge or carrier gas is first introduced into a plasma-generating region before the reactive gases are provided.

In one example, the cleaning process, such as the first operation 210 of method 200, includes maintaining an etching rate of the ammonium fluoride etching process based upon the ratio of hydrogen-containing precursor to fluorine-containing precursor. A greater amount of fluorine-containing precursor to hydrogen-containing precursor will produce an ammonium fluoride etchant with relatively greater reactivity. In one or more embodiments, the molar ratio of hydrogen-containing precursor to fluorine-containing precursor introduced is in a range of from about 1:3 to 3:1, such as from about 1:3, 1:2.5, 1:2, 1:1.5 or 1:1 to about 1.5:1, 2:1, 2.5:1, or 3:1, including the endpoint values and all values in between. The molar ratio of hydrogen-containing precursor to fluorine-containing precursor in the etching gas mixture may be set to uniformly remove silicon oxides from all types of different semiconductor substrate trench junction surfaces.

In one or more embodiments, the cleaning process, such as the first operation 210 of method 200, further comprises maintaining the semiconductor substrate at a first deposition temperature. The first deposition temperature permits the ammonium fluoride etchant to condense out of the plasma/carrier gas and deposit as a solid into the device feature, including along the feature sidewalls and feature bottom. In one or more embodiments, the first deposition temperature may be at a value that prevents substantial reaction of the deposited ammonium fluoride etchant with the native oxides present during deposition. The semiconductor substrate temperature may then be raised after deposition to facilitate regulation of the rate of reaction of the deposited ammonium fluoride etchant. In one or more embodiments, the first deposition temperature may be at a value where the ammonium fluoride etchant is deposited on the semiconductor substrate surfaces and immediately or near-immediately reacts with the silicon oxides present on the surfaces. The first deposition temperature may depend on other process conditions, such as the pressure around the semiconductor substrate. In one or more embodiments, the semiconductor substrate may be maintained at a first deposition temperature of less than 120° C., such as in a range of from about −30° C. to 120° C., such as from about −30° C., −20° C., −10° C., 0° C., 10° C., 20° C., 30° C., 40° C., 50° C., and 60° C. to 70° C., 75° C., 80°° C., 85° C., 90° C., 95° C., 100° C., 105° C., 110° C., 115° C., and 120° C., and such as in a range of from about 0° C. to 75° C., including the endpoint values and all values in between.

Upon reaction between the ammonium fluoride etchant and the native oxides, a silica salt forms. In one example of a silica salt that is formed, an ammonium hexafluorosilicate hydrate ((NH₄)₂SiF₆.H₂O) is present on the surfaces of the semiconductor substrate as a reaction product that is resultant where native oxide layers and bare silicon dioxide are present. Depending on the ratios of reactants introduced into the carrier gas/plasma, water, molecular hydrogen, and ammonia may also be present in the gas phase with the carrier gas. In some embodiments, the silica salt formed on the exposed surfaces are removed by heating the substrate to cause sublimation of the formed silica salt material and removal of the undesirable materials formed thereon.

In another example, the cleaning process performed in first operation 210 of method 200 includes generating a plasma formed with a carrier gas. The plasma/carrier gas combination may then be introduced to the surface of the semiconductor substrate with or without bias. In one or more embodiments, the carrier gas may comprise, consist, or consist essentially of a noble gas, such as argon, neon, and helium, and combinations thereof. In some examples, the hydrogen containing gas, such as H₂, and a carrier gas, such as argon (Ar), are provided to the surface of the semiconductor substrate while a bias is applied to the substrate.

Continuing from the end of the first operation 210 of method 200, the second operation 220 of method 200 shown in FIG. 4B includes forming a metal silicide layer on the exposed surfaces of each of the plurality of stacked contact structures 308, wherein forming the metal silicide layer on the exposed surfaces comprises selectively depositing a first metal layer on the exposed surfaces.

In FIG. 4B, a metal silicide layer 402 is shown formed by a first metal deposition process on top of the contact structures 308 and on top of substrate 302. Forming the metal silicide layer 402 on the exposed surfaces of each of the stacked contact structures includes selectively depositing a first metal layer on the exposed contact structures 308. In one or more embodiments, the first metal utilized for the first metal deposition process comprises titanium (Ti). In other embodiments, where the source/drain regions of the stacked contact structures 308 may be silicon-germanium (SiGe) or other p-type materials, the first metal utilized for the first metal deposition process may comprise a molybdenum silicide (MoSiₓ). In other embodiments, the Mo or W may be interchanged, or a combination of both materials employed.

In one or more embodiments, which may be combined with other embodiments, the first metal deposition process, such as the second operation 220 of method 200, includes selectively depositing the metal silicide layer 402, such as titanium, by any suitable chemical deposition technique, including but not limited to a CVD or ALD process. In one or more embodiments, which may be combined with other embodiments, the first metal deposition process, such as the second operation 220 of method 200, includes utilizing a metal containing precursor gas and a plasma to selectively deposit the metal silicide layer 402. In some embodiments, the metal containing precursor is selected from a group comprising titanium chloride (TiCl₄), molybdenum pentachloride (MoCl₅), molybdenum hexachloride (MoCl₆), molybdenum oxytetrachloride (MoOCl₄), tungsten pentachloride (WCl₅), tungsten hexachloride (WCl₆), tungsten pentabromide (WBr₅), tungsten hexabromide (WBr₆), or tris(3-hexyne) tungsten carbonyl (W(CO)(CH₃CH₂C≡CCH₂CH₃)₃). In some embodiments, the first metal deposition process is selective to the surfaces of the contact structures 308 over the dielectric material of inter-module insulating layer 304 which may be formed of silicon-containing dielectric material such as silicon oxide, or silicon nitride. Although not wanting to be bound by theory, the selective metal silicide deposition process is believed to have a selectivity of silicon (Si) or silicon/germanium (SiGe) over silicon oxide (SiO₂) and silicon nitride (SiₓN_{y}) in a range of about from 1.5:1 to greater than 30:1.

In one or more embodiments, the metal silicide layer 402 may include a metal such as titanium (Ti), molybdenum (Mo), cobalt (Co), nickel (Ni) or tungsten (W) that is formed on top of the surfaces of the contact structures 308 and may have a thickness in a range of from about 1 to 30 nm (about 10 to 300 A), such as in a range of from about 3 to 20 nm (about 30 to 200 A), such as in a range of from about 4 to about 25 nm (about 40 to 260 of method 200 A), such as in a range of from about 5 to about 20 nm (about 50 to 20 A), and such as about 10 nm (about 100 A). In one or more embodiments, which may be combined with other embodiments, the thickness of the metal silicide-containing material layer on top of the silicon dioxide substrate may be in a range of from about 0.1 to 3 nm (about 1 to 30 A). In one or more embodiments, the targeted thickness of the metal silicide layer 402, the first metal layer formed on the exposed contact structures 308, has a thickness of greater than or equal to about three nanometers. In one or more embodiments, the targeted thickness of the metal silicide layer 402 formed on top of the contact structures 308 may be determined based upon a desired corresponding Schottky Barrier Height. In one or more embodiments, the targeted thickness of the metal silicide layer 402 formed on top of the contact structures 308 may be determined based upon a desired corresponding gate structure contact resistance (R_{c}).

In some embodiments, as part of the process of depositing the metal silicide layer 402, a reducing agent that is reactive with a metal-containing precursor is introduced into the carrier gas along with a metal-containing precursor. The reducing agent may be a hydrogen-containing composition, such as molecular hydrogen (H₂), ammonia (NH₃), hydrazine (N₂H₄), silane (SiH₄), disilane (Si₂H₆), trisilane (Si₃H₈), and tetrasilane (Si₄H₁₀), or combinations thereof. The reducing agent acts as a proton donor to cause the metal-containing precursor to form a metallic film comprising the metal on top of the contact structures 308.

Continuing from the end of the second operation 220 of method 200, the third operation 230 of method 200 shown in FIG. 4C includes forming a second metal layer on the metal silicide layer 402, wherein forming the second metal layer on the first metal layer comprises selectively depositing the second metal layer 404 on the metal silicide layer 402. In one or more embodiments, the thickness of the second metal layer 404 formed on top of the metal silicide layer 402 may be at least about 3 nm. In one or more embodiments, the second metal layer 404 acts as a seed layer to improve the formation of a layer, or layers, disposed above of the second metal layer 404, for example, as a seed layer to improve the formation of a third metal layer, or a conductor, material disposed on the second metal layer 404.

In FIG. 4C, the second metal layer 404 shown is formed by a second metal deposition process on top of the metal silicide layer 402. In one or more embodiments, the metal utilized for the second metal deposition process may comprise a fluorine-free tungsten (FFW) containing precursor. In one or more embodiments, the FFW containing precursor may comprise tungsten pentachloride (WCl₅), tungsten hexachloride (WCl₆), tungsten oxytetrachloride (WOCl₄), tungsten dichloride dioxide (WO₂Cl₂), tungsten pentabromide (WBr₅), tungsten hexabromide (WBr₆), or combinations thereof. In one or more embodiments, the metal-containing precursor includes a fluorine-free metal organic, such as tris(3-hexyne) tungsten carbonyl (W(CO)(CH₃CH₂C≡CCH₂CH₃)₃). In yet other embodiments, the metal utilized for the second metal deposition process may comprise molybdenum (Mo) that is formed by use of molybdenum containing precursor such as molybdenum pentachloride (MoCl₅), molybdenum hexachloride (MoCl₆), or molybdenum oxytetrachloride (MoOCl₄)

In the one or more embodiments, which may be combined with other embodiments, the second metal deposition process, such as the third operation 230 of method 200, includes selectively depositing the second metal layer 404, such as FFW, by any suitable chemical deposition technique, including but not limited to a CVD or ALD. In one or more embodiments, the chemical deposition technique could include halide based CVD or ALD, for example WCl₅ plus diatomic hydrogen (H₂). In one or more embodiments, which may be combined with other embodiments, the second metal deposition process, such as the second operation 220 of method 200, includes utilizing a plasma with a carrier gas to selectively deposit the second metal layer 404. The plasma/carrier gas may then be introduced towards the surface of the semiconductor substrate. In one or more embodiments, which may be combined with other embodiments, the carrier gas comprises, consists, or consists essentially of a noble gas, such as argon, neon, and helium, and combinations thereof.

Continuing from the end of the third operation 230 of method 200, a fourth operation 240 of method 200 shown in FIG. 4D includes forming a third metal layer 409 on the second metal layer 404, wherein forming the third metal layer 409 on the second metal layer 404 comprises conformal deposition of the third metal layer 409 on the second metal layer 404.

In FIG. 4D, the third metal layer 409 shown is formed by a third metal deposition process on top of the second metal layer 404. In one or more embodiments, the metal utilized for the third metal deposition process may be comprised of an electrically conductive material. The electrically conductive material may include various metal alloys, metals, or conductive ceramics including but is not limited to, one or more of Aluminum (Al), chromium (Cr), cobalt (Co), copper (Cu), gold (Au), hafnium (Hf), iridium (Ir), iron (Fe), lanthanum (La), manganese (Mn), molybdenum (Mo), niobium (Nb), platinum (Pt), rhodium (Rh), ruthenium (Ru), silver (Si), tantalum (Ta), tin (Sn), titanium (Ti), tungsten (W), vanadium (V), yttrium (Y), zirconium (Zr), and combinations thereof.

In the one or more embodiments, which may be combined with other embodiments, the third metal deposition process, such as the fourth operation 240 of method 200, includes selectively depositing the third metal layer 409, by any suitable chemical conformal deposition technique, including but not limited to a CVD or ALD. In one or more embodiments, the thickness of the third metal layer 409 formed on top of the second metal layer 404 may be at least about 5 nanometers (nm).

In one or more embodiments, the third metal layer 409 acts as a seed layer to improve the formation of a layer, or layers, disposed above of the third metal layer 409, for example, as a seed layer to improve the formation of a subsequent metal layer, or a conductor, material disposed on the third metal layer 409.

Continuing from the fourth operation 240 of method 200, where a third metal layer 409 has been deposited on top of the second metal layer 404, the fifth operation 250 of method 200 shown in FIG. 4E includes filling the opening 401 with a conductor material.

In FIG. 4E, the opening 401 is shown filled with a conductor material 406 formed by a fourth metal deposition process on top of the third metal layer 409. In one or more embodiments, the conductor material utilized for the fourth metal deposition process may comprise a precursor that comprises tungsten hexafluoride (WF₆). In yet other embodiments, the conductor material utilized for the fourth metal deposition process may comprise molybdenum (Mo).

In the one or more embodiments, which may be combined with other embodiments, the fourth metal deposition process, such as the fifth operation 250 of method 200, includes selectively depositing the conductor material 406, such as a precursor that comprises WF₆, by any suitable chemical deposition technique, including but not limited to a CVD or ALD. In other embodiments, which may be combined with other embodiments, a conventional conformal chemical vapor deposition (CVD) or atomic layer deposition (ALD) process is used to fill the opening 401 with a conductor material.

In yet another other embodiments, which may be combined with other embodiments, the fourth metal deposition process, such as the fifth operation 250 of method 200, includes utilizing a metal containing precursor gas and a plasma to selectively deposit the conductor material 406 filling the opening 401. In yet another other embodiments the fourth metal deposition process, such as the fifth operation 250 of method 200, includes using PVD, PVD and pullback, or PVD and direct selective fill to selectively deposit the conductor material 406 filling the opening 401.

Continuing from the fifth operation 250 of method 200, the sixth operation 260 of method 200 shown in FIG. 4F includes depositing a capping layer 408 on the conductor material 406. In FIG. 4F, a capping layer 408 is shown deposited by a fifth metal deposition process on top of the conductor material 406 filling the opening 401. In one or more embodiments, the material utilized for the fourth metal deposition process may comprise a tungsten (W). In other embodiments, the conductor material utilized for the second metal deposition process may comprise molybdenum (Mo).

In the one or more embodiments, which may be combined with other embodiments, the fifth metal deposition process, such as the sixth operation 260 of method 200, includes selectively depositing the capping layer 408 on top of the conductor material 406 filling the opening 401 by any suitable chemical deposition technique, including but not limited to a CVD or ALD. In other embodiments, which may be combined with other embodiments, a conventional conformal chemical vapor deposition (CVD) or atomic layer deposition (ALD) process is used to deposit the capping layer 408.

In yet another other embodiment, which may be combined with other embodiments, the fifth metal deposition process, such as the sixth operation 260 of method 200, includes utilizing a metal containing precursor gas and a plasma to deposit the capping layer 408 on top of the conductor material 406 filling the opening 401.

In yet another other embodiments the fourth metal deposition process, such as the fifth operation 250 of method 200, includes using PVD, PVD and pullback, or PVD and direct selective fill to selectively deposit the conductor material 406 filling the opening 401.

### First Alternate Fill Process

An alternative embodiment utilizing method 200 of FIG. 2 is best understood with reference to FIGS. 4G-I. FIGS. 4G-I illustrate cross-sectional views of a portion of a semiconductor structure 300 according to embodiments described herein. The cross-sectional views, FIGS. 4G-I, view of a portion of a semiconductor structure 300 from 4X to 4X′ in FIG. 3, viewed along the Y-direction.

Continuing from the third operation 230 of method 200, described early in reference to FIG. 4C, the fourth operation 240 of method 200 shown in FIG. 4G includes forming a third metal layer 409 on the second metal layer 404, wherein forming the third metal layer 409 on the first metal layer comprises depositing the third metal layer 409 on the second metal layer 404, and the substrate 302 by use of physical vapor deposition (PVD) process.

In one or more embodiments, the metal utilized for the third metal deposition process may be comprised of an electrically conductive material. The electrically conductive material may include various metal alloys, metals, or conductive ceramics including but is not limited to, one or more of Aluminum (Al), chromium (Cr), cobalt (Co), copper (Cu), gold (Au), hafnium (Hf), iridium (Ir), iron (Fe), lanthanum (La), manganese (Mn), molybdenum (Mo), niobium (Nb), platinum (Pt), rhodium (Rh), ruthenium (Ru), silver (Si), tantalum (Ta), tin (Sn), titanium (Ti), tungsten (W), vanadium (V), yttrium (Y), zirconium (Zr), and combinations thereof.

In the one or more embodiments, which may be combined with other embodiments, the third metal deposition process, such as the fourth operation 240 of method 200, includes selectively depositing the third metal layer 409, by any suitable deposition technique, including but not limited to PVD, CVD, or ALD. In one or more embodiments, the thickness of the third metal layer 409 formed on top of the second metal layer 404 may be at least about 5 nanometers (nm).

In FIG. 4G, the third metal deposition process is used to deposit a metal layer on top of the second metal layer 404, and the substrate 302. In one or more embodiments, the metal utilized for the third metal deposition process may be comprised of an electrically conductive material. The electrically conductive material may include various metal alloys, metals, or conductive ceramics including but is not limited to, one or more of Aluminum (Al), chromium (Cr), cobalt (Co), copper (Cu), gold (Au), hafnium (Hf), iridium (Ir), iron (Fe), lanthanum (La), manganese (Mn), molybdenum (Mo), niobium (Nb), platinum (Pt), rhodium (Rh), ruthenium (Ru), silver (Si), tantalum (Ta), tin (Sn), titanium (Ti), tungsten (W), vanadium (V), yttrium (Y), zirconium (Zr), and combinations thereof.

The third metal deposition process, such as the fourth operation 240 of method 200, includes depositing the third metal layer 409, by use of PVD deposition technique. In one or more embodiments, which may be combined with other embodiments, the third metal deposition process, such as the fourth operation 240 of method 200, includes sputtering a material from a target that contains a metal or metal alloy that includes W, Mo, Co, Ti, Ru, Cu or other useful metal to form the third metal layer 409. In one example, the third metal layer 409 comprises W or Mo. In some embodiments, the substrate is biased during the third metal deposition process to improve the bottom coverage of the formed third metal layer 409 (i.e., third metal layer 409 at the bottom of the opening 401 in FIG. 4G). The substrate biasing process is performed by RF, DC or grounding an electrode disposed within a substrate support, over which the substrate is positioned below the PVD target, during a sputtering deposition process. The thickness of the third metal layer 409 formed on top of the second metal layer 404, and the substrate 302, may be at least about 5 nm.

Continuing from the fourth operation 240 of method 200 described in FIG. 4G, where a third metal layer 409 has been deposited on top of the second metal layer 404, the fifth operation 250 of method 200 shown in FIG. 4H includes filling the opening 401 with a conductor material 406.

In FIG. 4H, the opening 401 is shown filled with a conductor material 406 formed by a fourth metal deposition process on top of the third metal layer 409. In one or more embodiments, the conductor material 406 utilized for the fourth metal deposition process may comprise a precursor that comprises tungsten hexafluoride (WF₆). In yet other embodiments, the conductor material utilized for the fourth metal deposition process may comprise molybdenum (Mo), which can, for example, be deposited by use of a molybdenum pentachloride (MoCl₅) or molybdenum hexafluoride (MoF₆) precursor.

In the one or more embodiments, which may be combined with other embodiments, the fourth metal deposition process, such as the fifth operation 250 of method 200, includes depositing the conductor material 406, such as a precursor that comprises WF₆, by any suitable chemical deposition technique, including but not limited to a CVD or ALD. In other embodiments, which may be combined with other embodiments, a conventional conformal chemical vapor deposition (CVD) or atomic layer deposition (ALD) process is used to fill the opening 401 with a conductor material.

In yet another other embodiment, which may be combined with other embodiments, the fourth metal deposition process, such as the fifth operation 250 of method 200, includes utilizing a metal containing precursor gas and a plasma to deposit the conductor material 406 filling the opening 401. In yet another other embodiments the fourth metal deposition process, such as the fifth operation 250 of method 200, includes using PVD, PVD and pullback, or PVD and direct selective fill to selectively deposit the conductor material 406 filling the opening 401.

Continuing from the fifth operation 250 of method 200 shown in FIG. 4H, the sixth operation 260 of method 200 illustrated in FIG. 4I includes depositing a capping layer 408 on the conductor material 406. In the one or more embodiments, which may be combined with other embodiments, the fifth metal deposition process, such as the sixth operation 260 of method 200, includes depositing the capping layer 408 on top of the conductor material 406 filling the opening 401 by any suitable chemical deposition technique, including but not limited to a CVD or ALD. In other embodiments, which may be combined with other embodiments, a conventional conformal chemical vapor deposition (CVD) or atomic layer deposition (ALD) process is used to deposit the capping layer 408.

In one embodiment, which may be combined with other embodiments, the fifth metal deposition process, such as the sixth operation 260 of method 200, includes utilizing a metal containing precursor gas and a plasma to deposit the capping layer 408 on top of the conductor material 406 filling the opening 401.

### Second Alternate Fill Process

Another alternative embodiment utilizing method 200 of FIG. 2 is best understood with reference to FIG. 4J. FIG. 4J illustrates a cross-sectional view of a portion of a semiconductor structure 300 according to embodiments described herein. The cross-sectional view of FIG. 4J views a portion of a semiconductor structure 300 from 4X to 4X′ in FIG. 3, viewed along the Y-direction.

Continuing from the end of the first operation 210 described earlier, the second operation 220 of method 200 illustrated in FIG. 4J includes forming a metal silicide layer on the exposed surfaces of each of the plurality of stacked contact structures 308 and on the surface of the substrate 302, wherein forming the metal silicide layer on the exposed surfaces comprises selectively depositing a first metal layer on the exposed surfaces. Additionally illustrated in FIG. 4J, the third operation 230 of method 200 includes forming a second metal layer on the metal silicide layer 402, wherein forming the second metal layer on the first metal layer comprises selectively depositing the second metal layer 404 on the metal silicide layer 402.

In FIG. 4J, a metal silicide layer 402 is shown formed by a first metal deposition process on top of the contact structures 308 and on top of substrate 302. Forming the metal silicide layer 402 on the exposed surfaces of each of the stacked contact structures and substrate 302 includes selectively depositing a first metal layer on exposed contact structures 308. In one or more embodiments, the first metal utilized for the first metal deposition process comprises titanium (Ti). In other embodiments, where the substrate 302 may be silicon-germanium (SiGe) or other p-type materials, the first metal utilized for the first metal deposition process comprises may comprise a molybdenum silicide (MoSiₓ). In other embodiments, the Mo or W may be interchanged, or a combination of both materials employed.

In one or more embodiments, which may be combined with other embodiments, the first metal deposition process, such as the second operation 220 of method 200, includes selectively depositing the metal silicide layer 402, such as titanium, by any suitable chemical deposition technique, including but not limited to a CVD or ALD. In one or more embodiments, which may be combined with other embodiments, the first metal deposition process, such as the second operation 220 of method 200, includes utilizing a metal containing precursor gas and a plasma to selectively deposit the metal silicide layer 402.

The first metal deposition process is selective to the contact structures 308 and substrate 302 over the dielectric material of inter-module insulating layer 304 which may be formed of silicon-containing dielectric material such as silicon oxide, or silicon nitride. Although not wanting to be bound by theory, the selective metal silicide deposition process is believed to have a selectivity of silicon (Si) or silicon/germanium (SiGe) over silicon oxide (SiO₂) and silicon nitride (SiₓN_{y}) in a range of about from 1.5:1 to greater than 30:1.

In one or more embodiments, the thickness of the metal silicide layer 402 formed on top of the contact structures 308 and substrate 302 may be in a range of from about 1 to 30 nm (about 10 to 300 A), such as in a range of from about 3 to 20 nm (about 30 to 200 A), such as in a range of from about 4 to about 25 nm (about 40 to 260 of method 200 A), such as in a range of from about 5 to about 20 nm (about 50 to 20 A), and such as about 10 nm (about 100 A). In one or more embodiments, which may be combined with other embodiments, the thickness of the metal silicide-containing material layer on top of the silicon dioxide substrate may be in a range of from about 0.1 to 3 nm (about 1 to 30 A). In one or more embodiments, the targeted thickness of the metal silicide layer 402 formed on top of the contact structures 308 may be determined based upon a desired corresponding Schottky Barrier Height. In one or more embodiments, the targeted thickness of the metal silicide layer 402 formed on top of the contact structures 308 may be determined based upon a desired corresponding gate structure contact resistance (R_{c}).

In one or more embodiments, the deposition time of the first metal deposition process, such as the second operation 220 of method 200, which includes selectively depositing the metal silicide layer 402, may take less than about 100 seconds.

The second metal layer 404 shown is formed by a second metal deposition process on top of the metal silicide layer 402. In one or more embodiments, the metal utilized for the second metal deposition process may comprise a fluorine-free tungsten (FFW) containing precursor. In one or more embodiments, the FFW containing precursor may comprise tungsten pentachloride (WCl₅), tungsten hexachloride (WCl₆), tungsten pentabromide (WBr₅), or tungsten hexabromide (WBr₆). In yet other embodiments, the metal precursor utilized for the second metal deposition process may comprise molybdenum (Mo), such as a precursor comprising molybdenum pentachloride (MoCl₅), molybdenum hexachloride (MoCl₆), or molybdenum oxytetrachloride (MoOCl₄). The second metal deposition process is selective to the metal silicide layer 402 which may be formed titanium silicide (TiSi₂). Although not wanting to be bound by theory, the selective second metal deposition process is believed to have a selectivity of TiSi₂ over silicon oxide (SiO₂) and silicon nitride (SiₓN_{y}) in a range of about from 1.5:1 to greater than 30:1. In one or more embodiments, the thickness of the second metal layer 404 formed on top of the metal silicide layer 402 may be at least about 3 nm.

In the one or more embodiments, which may be combined with other embodiments, the second metal deposition process, such as the third operation 230 of method 200, includes selectively depositing the second metal layer 404, such as FFW, by any suitable chemical deposition technique, including but not limited to a CVD or ALD. In one or more embodiments, the chemical deposition technique could include halide based CVD or ALD, for example WCl₅ plus diatomic hydrogen (H₂). In one or more embodiments, which may be combined with other embodiments, the second metal deposition process, such as the second operation 220 of method 200, includes utilizing a metal containing precursor gas and a plasma to selectively deposit the second metal layer 404. The plasma/carrier gas may then be introduced towards the surface of the semiconductor substrate.

Following the second operation 220 of method 200, and the third operation 230 of method 200 within the second alternate fill process sequence discussed in relation to FIG. 4J, the remaining operations, the fourth operation 240 of method 200, the fifth operation 250 of method 200, and the sixth operation 260 of method 200 are performed as described above.

As may be appreciated by one of ordinary skill in the art, one or more configurations of semiconductor substrates or other portions of the same semiconductor substrate and features, such as contact junctions, may benefit from the processes and methods described.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram. Further, the relative dimensions, arrangement, shapes, and orientations of features presented in the figures are representative. One of ordinary skill in the art will appreciate that, in practice, each dimension, position, shape, and orientation, may differ, for example a rectangular feature may have a diamond or rounded shape in practice. Accordingly, the scope should not be considered limited to the specific dimensions, arrangement, shapes, and orientations shown in the figures.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a nonspecific plane of reference. This non-specific plane of reference may be vertical, horizontal, or other angular orientation.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

As used, the term “determining” encompasses a wide variety of actions. For example, “determining” may include calculating, computing, processing, deriving, investigating, looking up, for example, looking up in a table, a database or another data structure, and ascertaining. Also, “determining” may include receiving, for example, receiving information, and accessing, for example, accessing data in a memory. Also, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112(f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A method of forming a contact structure on a semiconductor substrate, comprising:
removing material from surfaces of a feature formed in a surface of a substrate, wherein
the feature comprises a plurality of contact structures disposed within the feature formed in the substrate,
the contact structures comprise a plurality of contacts that each comprise silicon (Si) or silicon germanium (SiGe),
each of the plurality of contacts are spaced apart in a first direction by a dielectric layer, and
the method of removing material comprises:
selectively forming a reaction product material over a surface of each of the plurality of contacts; and
heating the substrate to a first temperature to remove the reaction product material from the surface of each of the plurality of contacts;
selectively forming a first metal layer on the surface of each of the plurality of contacts;
forming a second metal layer on the first metal layer, wherein forming the second metal layer on the first metal layer comprises selectively depositing the second metal layer on the first metal layer, and selectively forming the second metal layer comprises exposing the surface of the selectively formed first metal layer to a fluorine-free metal containing precursor to form the second metal layer;
filling the feature with a conductor material, wherein the conductor material comprises tungsten (W) or molybdenum (Mo); and
depositing a capping layer on the conductor material.

2. The method of claim 1, wherein the reaction product material will include a silica salt containing material.

3. The method of claim 2, wherein silica salt containing material comprises an ammonium hexafluorosilicate.

4. The method of claim 3, wherein the first metal layer comprises a metal silicide layer that comprises titanium.

5. The method of claim 1, wherein the fluorine-free metal containing precursor comprises tungsten and a halogen containing gas.

6. The method of claim 5, wherein the fluorine-free metal containing precursor is selected from a group consisting of tungsten pentachloride (WCl₅), tungsten hexachloride (WCl₆), tungsten pentabromide (WBr₅), and tungsten hexabromide (WBr₆).

7. The method of claim 1, wherein the fluorine-free metal containing precursor comprises molybdenum and a halogen containing gas.

8. The method of claim 7, wherein the fluorine-free metal containing precursor is selected from a group consisting of molybdenum pentachloride (MoCl₅), molybdenum hexachloride (MoCl₆), and molybdenum oxytetrachloride (MoOCl₄).

9. The method of claim 8, wherein filling the feature with the conductor material comprises selectively forming the conductor material on the first metal layer, which comprises exposing the first metal layer to a fluorine-containing precursor.

10. The method of claim 9, wherein selectively forming the conductor material comprises exposing the second metal layer to a metal precursor that comprises molybdenum (Mo).

11. The method of claim 9, wherein selectively forming the conductor material comprises exposing the second metal layer to a metal precursor that comprises tungsten hexafluoride (WF₆).

12. The method of claim 1, wherein the first metal layer formed on the exposed surfaces comprises has a thickness of greater than or equal to about three nanometers.

13. The method of claim 12, wherein the first metal layer on the exposed surfaces comprises a first metal layer target thickness determined by a corresponding Schottky Barrier Height (SBH).

14. The method of claim 1, wherein selectively depositing the second metal layer on an outer surface of the first metal layer on the exposed surfaces comprises a second metal layer thickness greater than or equal to about three nanometers.

15. The method of claim 1, wherein selectively forming a first metal layer on the plurality of contacts comprises introducing a hydrogen-containing reducer and a first metal containing precursor to the contact surface such that a first metal layer forms on top of the contact surface that comprises silicon or silicon germanium.

16. The method of claim 15, wherein the hydrogen-containing reducer includes molecular hydrogen (H₂).

17. The method of claim 12, wherein the first metal layer on the exposed surfaces comprises a first metal layer target thickness determined by a corresponding gate contact structure resistance (Rc).

18. The method of claim 1, wherein the second metal layer provides an Oxygen (O) barrier, or a Fluorine (F) barrier, or both an O and F barrier.

19. The method of claim 1, wherein the second metal layer acts as a seed layer for the conductor material.

20. The method of claim 1, further comprising forming a third metal layer on the second metal layer, wherein forming the third metal layer on the second metal layer comprises selectively depositing the third metal layer on the second metal layer.
